(19) United States
(12) Patent Application Publication
(10) Pub. No.: US 2011/0073038 A1
(43) Pub. Date: Mar. 31, 2011

(54) GAS DISTRIBUTION PLATE AND APPARATUS USING THE SAME

(75) Inventors: Jung-Chen CHIEN, Hsinchu County (TW); Jun-Chin Liu, Hsinchu City (TW); Hung-Jen Yang, Hsinchu City (TW); Tean-Mu Shen, Hsinchu City (TW); Muh-Wang Liang, Miaoli County (TW)

(73) Assignee: INDUSTRIAL TECHNOLOGY RESEARCH INSTITUTE, Hsinchu (TW)

(21) Appl. No.: 12/616,203

(22) Filed: Nov. 11, 2009

(30) Foreign Application Priority Data
Sep. 25, 2009 (TW) 098132442

(51) Int. Cl. C23C 16/455

(52) U.S. Cl. 118/715

(57) ABSTRACT

The present invention provides a gas distribution plate for providing at least two gas flowing channel. In one embodiment, the gas distribution plate has a first flowing channel, at least a second flowing channel disposed around the first flowing channel, and a tapered opening communicating with the first and the second flowing channel. In another embodiment, the gas distribution plate has a first flowing channel passing through a first and a second surface of the gas distribution plate, a second flowing channel paralleling to the first surface and a third flowing channel disposed at the second surface and communicating with the second flowing channel. The ends of the first and the third flowing channel have a tapered opening respectively. Besides, the present further provides a gas distribution apparatus for allowing at least two separate gases to be delivered independently into a process chamber while enabling the gases to be mixed completely after entering the processing chamber.

### FIELD OF THE INVENTION

The present invention relates to a gas supply technique, and more particularly, to a gas distribution plate and the apparatuses using the same that is capable of supplying at least two reaction gases.

### BACKGROUND OF THE INVENTION

With rapid advance and popularity of using means of chemical vapor deposition (CVD) in thin film coating process, it is becoming more and more important to have a gas distribution module capable of spraying gases into its corresponding reaction chamber uniformly.

Please refer to FIG. 1, which shows the arrangement of a common gas distribution module. As shown in FIG. 1, there is a carrier 11 being arranged inside a chamber 10 for carrying a substrate 12 to be processed while enabling the substrate 12 to be located at a position corresponding to an inlet channel 100 of the chamber 10. Moreover, the inlet channel 100 is connected with a gas distribution module 13, whereas the gas distribution module 13 can be a metal circular plate having a plurality of hole formed therein in a symmetrical manner so as to enable the gases entering into the chamber 10 through the inlet channel 100 to be sprayed uniformly onto the substrate 12. However, the uniformity resulting from the aforesaid conventional gas distribution module 13 is usually not satisfactory that it is common to have a buffer zone 14 arranged between the inlet channel 100 and the gas distribution module 13 for improvement, by that the gases entering from the gas distribution module can first be stabilized by the buffering of the buffer zone 14 before it is sprayed inside the chamber 10 through the gas distribution module 13, as shown in FIG. 2.

Nevertheless, the aforesaid arrangement is only proper for thin film coating process using low-flow gas, but is not capable of handling those thin film coating processes using high-flow gas since the use of simply only a layer of buffer zone 14 and the gas distribution module 13 is not sufficient. As shown in FIG. 3, when the gas entering area is fixed, the larger the flow is, the faster the gas is going to flow, by that the gas flowing through the center of the gas distribution module 13 will flow faster than those through the sides thereof, and thus more gas is going to accumulate at the center of the substrate 12 while causing the coating process with prove uniformity.

There are already many studies relating to the improvement of the gas distribution module. One of which is a gas distribution module disclosed in U.S. Pat. No. 6,921,437. In this gas distribution module, since the gases to be used in a coating process will be mixed in advance, not only it is unsuitable for those coating processes requiring the use of more than one gases that can not be mixed in advance for preventing they from reacting with each other, but also it can not be achieved without the use of some very complex piping arrangement and thus it can be very difficult to build and very costly as well.

Another such study is disclosed in U.S. Pat. No. 6,478,872, which describes a method of delivering gas into reaction chamber and shower head used to deliver gas. However, although the aforesaid gas distribution design is capable of enabling gases to be mixed and spray with sufficient uniformity, it is still very difficult and costly to build since its structure is very complex.

One another such study is disclosed in U.S. Pub. No. 2007/0163440, which describes a gas separation type showerhead. Although the aforesaid showerhead is capable of delivering gases with sufficient uniformity without having the gases to be mixed in advance, it is still disadvantageous in that: the showerhead can be very difficult and costly to build since its structure is very complex.

Furthermore, another such study is disclosed in U.S. Pat. No. 6,148,761, which describes a dual channel gas distribution plate. The dual channel gas distribution plate, being provided as a portion of a gas delivery system to a process chamber, has at least two sets of gas pathways disposed therein for allowing at least two separate gases to be delivered independently into a process chamber. In one embodiment, a first gas pathway, which includes a first set of vertical channels, is formed through the gas distribution plate, and a second gas pathway, which includes a second set of vertical channels, is formed through a portion of the gas distribution plate and connected to a set of interconnecting horizontal channels in the gas distribution plate, where the second gas pathway maintains fluidic separation from the first gas pathway, prior to the gases entering the process chamber.

### SUMMARY OF THE INVENTION

The object of the present invention is to provide a gas distribution plate and the apparatuses using the same that is capable of supplying at least two gases into a process chamber through their corresponding independent gas flowing channels while maintaining fluidic separation between the gas flowing channels prior to the gases entering the process chamber.

Another object of the invention is to provide a gas distribution apparatus, configured with tapered openings connected to the independent gas flowing channels of its gas distribution plate, by that the flow speeds of the gases are reduced so as to diffuse them and thus enable the same to be mixed completely prior to the gases entering the process chamber.

In one embodiment of the invention, the present invention provides a gas distribution plate, which comprises: a frame, having a recess formed at the center thereof; a first channel, connected to the recess by an end thereof while enabling another end thereof to penetrate the frame; a tapered opening, capable of communicating with the first channel; and at least a second channel, formed on the frame while enabling the same to communicate with the tapered opening.

In another embodiment of the invention, the present invention provides a gas distribution apparatus, which comprises: a gas guidance section, for guiding the flow of a first gas; a gas distribution plate, connected to the gas guidance section and comprising: a frame, having a recess formed at the center thereof; a plurality of first channels, each being configured for enabling the same to communicate with the gas guidance section so as to received the first gas therefrom; a plurality of second channels, being arranged in a manner that there is at least one such second channels disposed at a side of each first channel to be used for guiding the flow of a second gas; and a plurality of tapered openings, each being formed for enabling the same to communicate with one corresponding first channel and the at least one second channels disposed at the side of the corresponding first channel.

Furthermore, in another embodiment of the invention, the present invention provides a gas distribution plate, comprising: a frame with a first surface and a second surface, having a recess formed at the center thereof; a first channel, being formed penetrating through the recess of the frame; a second channel, formed inside the frame while allowing the center axis of the second channel to align parallel with the first surface; and a third channel, formed on the second surface of the frame while allowing the same to communicate with the second channel; wherein, the first channel further has a first tapered opening located on the second surface, and the third channel further has a second tapered opening located on the second surface.

In addition, in another embodiment of the invention, the present invention provides a gas distribution apparatus, comprising: a gas guidance section, for guiding the flow of a first gas; a gas distribution plate, connected to the gas guidance section and comprising: a frame with a first surface and a second surface, having a recess formed at the center thereof; a plurality of first channels, each being formed penetrating through the recess of the frame to be used for guiding the flow of a second gas; a plurality of second channels, each being formed inside the frame while allowing the center axis of each second channel to align parallel with the first surface so as to be used for guiding the flow of the first gas; and a plurality of third channel, formed on the second surface of the frame while allowing the same to communicate with their corresponding second channels; wherein, each first channel further has a first tapered opening located on the second surface, and each third channel further has a second tapered opening located on the second surface.

Further scope of applicability of the present application will become more apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given herein below and the accompanying drawings which are given by way of illustration only, and thus are not limitative of the present invention and wherein:

FIG. 1 to FIG. 3 show the arrangement of a common gas distribution module and the operation thereof as well.

FIG. 4A is a top view of a gas distribution plate according to a first embodiment of the invention.

FIG. 4B is an A-A sectional view of FIG. 4A.

FIG. 5A and FIG. 5B are schematic diagrams showing respectively the arrangement of a second channel and a first channel.

FIG. 6 is a schematic diagram showing a gas distribution apparatus according to a first embodiment of the invention.

FIG. 7A and FIG. 7B are respectively a top view and an A-A sectional view of a first frame used in the embodiment of FIG. 6.

FIG. 7C is a schematic diagram showing a first frame according to another embodiment of the invention.

FIG. 8 is a sectional view of a gas distribution apparatus using the gas distribution plate of FIG. 4A.

FIG. 9 is a schematic diagram showing how a first gas and a second gas are flowing in a gas distribution plate of the invention.

FIG. 10A and FIG. 10B are respectively a top view and a D-D sectional view of a gas distribution plate according to a second embodiment of the invention.

FIG. 11 is a schematic diagram showing a gas distribution apparatus according to a second embodiment of the invention.

FIG. 12A and FIG. 12B are respectively a top view and a sectional view of a first frame used in the embodiment of FIG. 11.

FIG. 13A and FIG. 13B are schematic diagrams showing how a first gas and a second gas are mixed with and without the formation of tapered openings in respective.

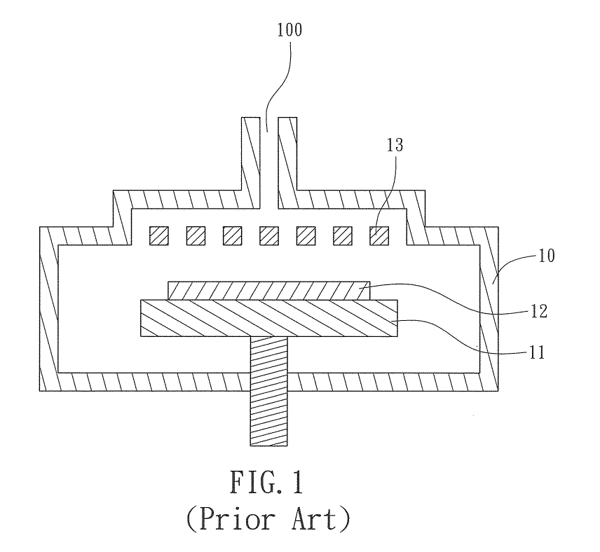

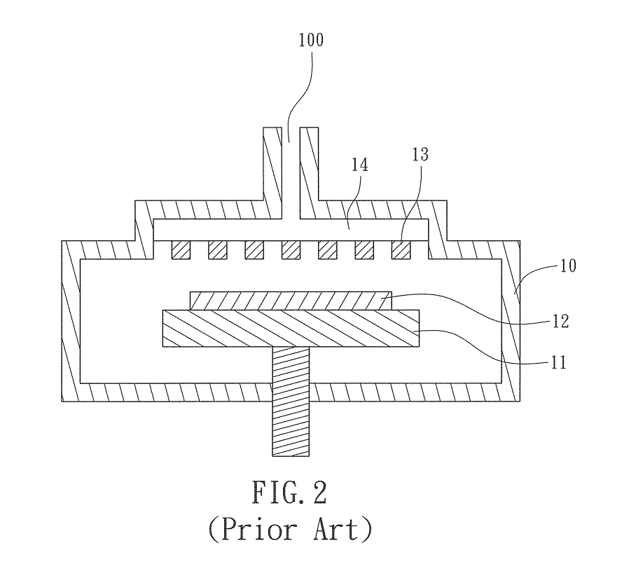

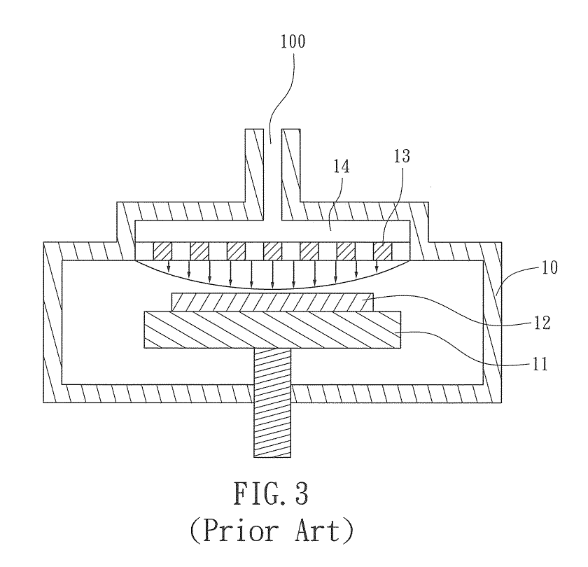

### DESCRIPTION OF THE EXEMPLARY EMBODIMENTS

For your esteemed members of reviewing committee to further understand and recognize the fulfilled functions and structural characteristics of the invention, several exemplary embodiments cooperating with detailed description are presented as the follows.

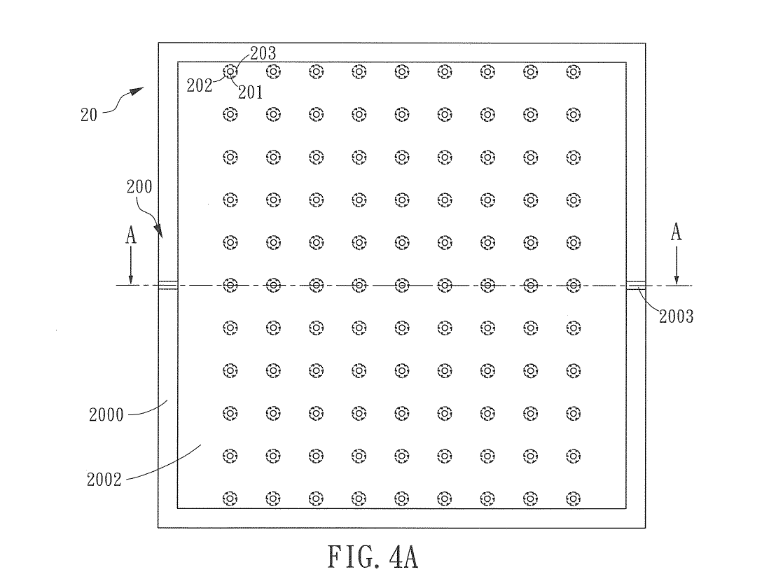

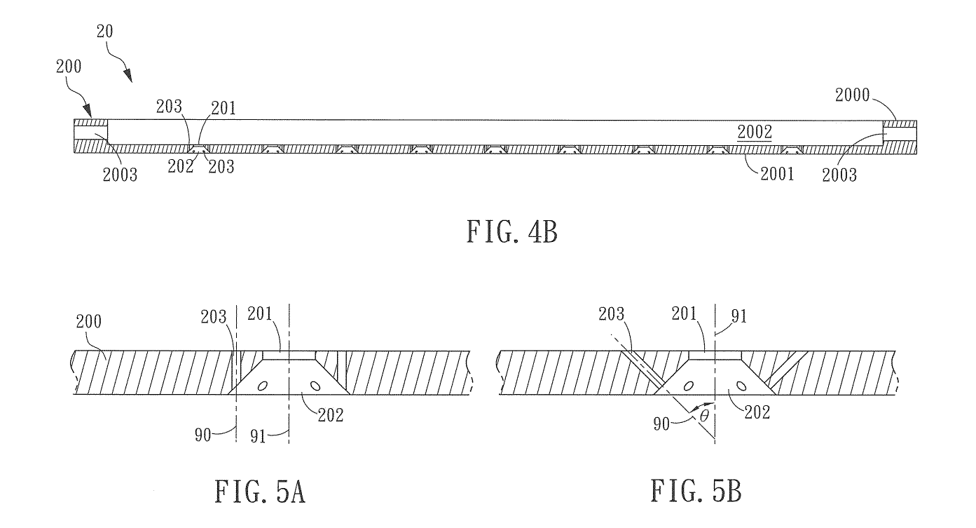

Please refer to FIG. 4A and FIG. 4B, which is a top view of a gas distribution plate according to a first embodiment of the invention and an A-A sectional view of FIG. 4A. As shown in FIG. 4A and FIG. 4B, the gas distribution plate 20 comprises: a frame 200, a plurality of first channel 201, a plurality of tapered openings 202, and a plurality of second channel 203. It is noted that the front end of each first channel 201 is formed as a straight hole while allowing the rear end of each first channel 202 to connect to its corresponding tapered opening 202. Moreover, the frame 200, being formed with a first surface 2000 and a second surface 2001, is configured with a recess 2002 at the center thereof as the recess 2002 can be formed by a means selected from the group consisting of: a means for performing a mechanical process upon the center of the frame 200, and a means for welding pieces of the frame 200 together while allowing the recess 2002 to be formed at the center thereof. In addition, there is at least one gas supply channel 2003 formed on the sidewall of the recess 2002 at a position where can be selected at will. In this embodiment, there are two gas supply channels 2003 being arranged respectively at the two sidewalls of the recess 2002. However, the amount of such gas supply channels 2003 capable of being formed on each sidewall is not limited thereby and thus there can be more than two such gas supply channels 2003 being formed on each sidewall as required.

In this embodiment, each first channel 201 is configured boring through the bottom of the recess 2002 and the second surface 2001 so as to connect an end of the referring first channel 20 with the recess 2002. In addition, for each first channel 201, there is at least one second channel 203 formed at a side thereof. It is note that the amount of such second channel 203 for each first channel 201 can be determined at will, nevertheless, there are six second channel 203 for each first channel 201 that is disposed surrounding the tapered opening 202 of the referring first channel 201 while enabling each second channel 203 to connect with referring first channel 201 by an end thereof and simultaneously connect with the recess 2002 by another end thereof. Please refer to FIG. 5A and FIG. 5B, which are schematic diagrams showing respectively the arrangement of a second channel and a first channel. In FIG. 5A, the center axis 90 of the second channel 203 is arranged parallel with the center axis 91 of the first channel 201. However, in FIG. 5B, the first and the second channels 201, 203 are arranged for forming an included angle θ between the center axis 90 of the second channel 203 and the center axis 91 of the first channel 201.

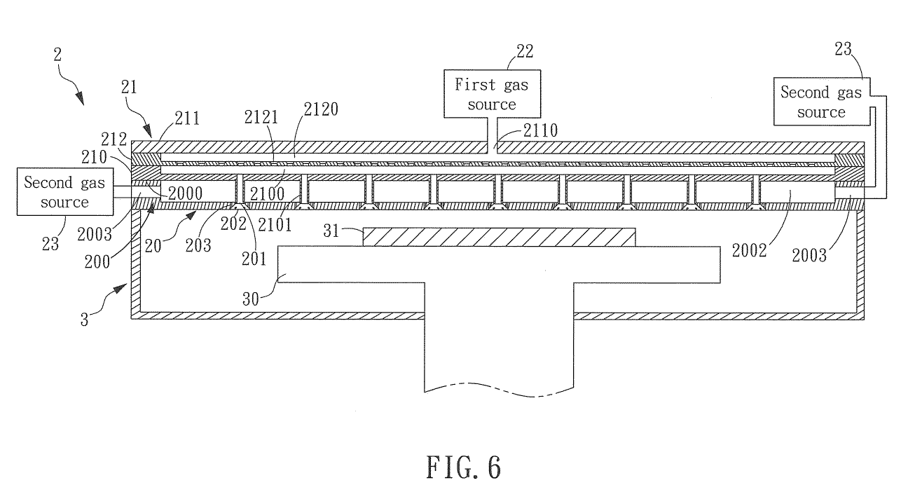

Please refer to FIG. 6, which is a schematic diagram showing a gas distribution apparatus according to a first embodiment of the invention. The gas distribution apparatus 2 employs the gas distribution plate of FIG. 4 as its gas distribution mechanism for enabling two separate gases to be delivered independently into a process chamber. In this embodiment, the gas distribution apparatus 2 is disposed on a process chamber 3, whereas the process chamber 3 can be a process chamber designed for performing chemical vapor deposition (CVD) process, or for physical vapor deposition (PVD) process, or for an etching process, but is not limited thereby. It is noted that there is a carrier 30 being arranged inside the process chamber 3 for carrying a substrate 31 to be processed and the substrate 31 can be a silicon substrate or a glass substrate, but is not limited thereby. Moreover, the gas distribution apparatus 2 further comprises: a gas guidance section 21; and a gas distribution plate 20, being arranged connecting to the gas guidance section 21; in which the gas guidance section 21 is coupled to a first gas source 22 for guiding the flow of a first gas from the first gas source 22 to the gas distribution plate 20; and the gas distribution plate 20 is further composed of: a first frame 210, a second frame 211 and a third frame 212 in a manner that the first frame is disposed on the first surface 2000 of the frame 200.

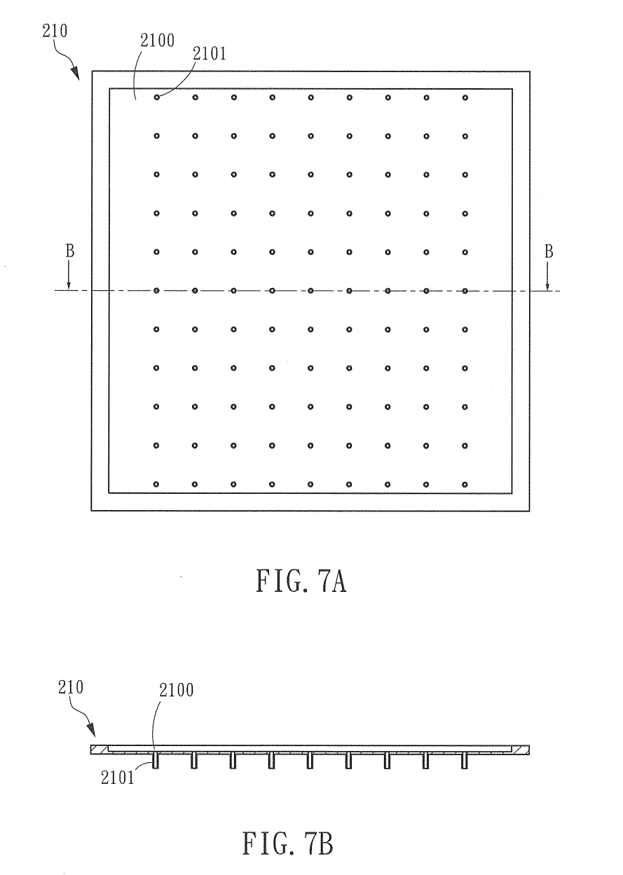

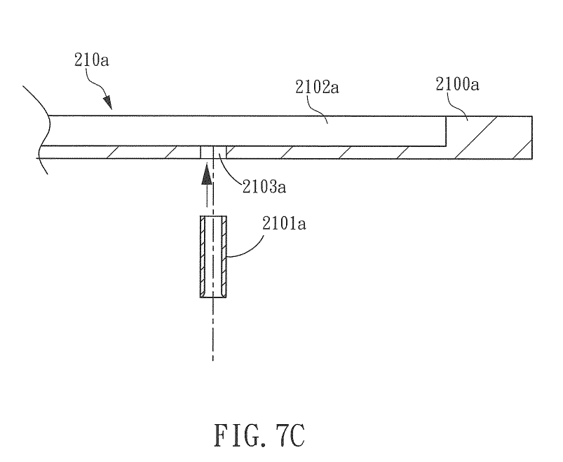

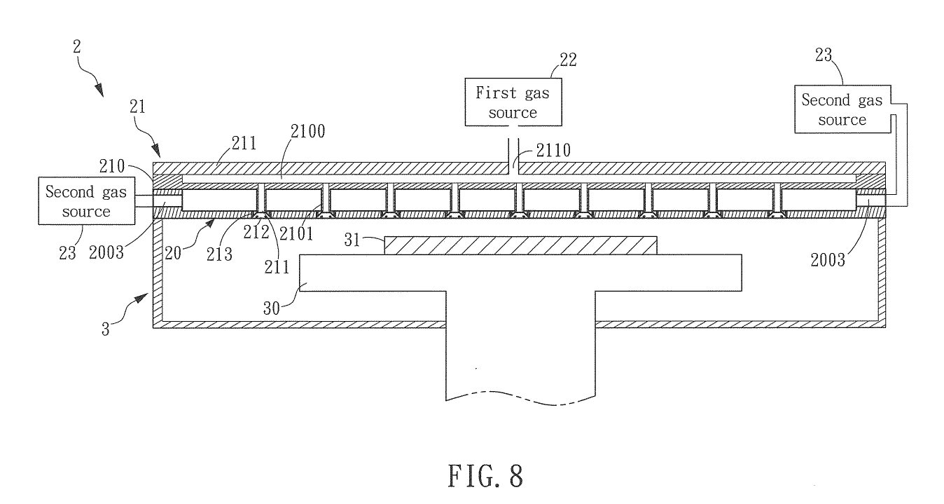

Please refer to FIG. 7A and FIG. 7B, which are respectively a top view and an A-A sectional view of a first frame used in the embodiment of FIG. 6. As shown in FIG. 7A and FIG. 7B, the first frame 210 has a first recess 2100 formed on a top side thereof and a plurality of protruding tubes 2101 at a bottom side thereof opposite to the top side while enabling each tube to communicate with the first recess 2100 by an end thereof as each is further capable of communicate with its corresponding first channel 210 through another end thereof. Similarly, the second frame 211 has an air hole 2110 which is connected with the first gas source so as to be used for the first gas to flow therethrough; and the third frame 212, being sandwiching between the first frame 210 and the second frame 211, is configured with a second recess 2120 in a manner that there are a plurality of via holes 2121 formed on the bottom of the second recess 2120 while enabling the plural via holes 2121 to communicate with the first recess 2100. In another embodiment as shown in FIG. 8, there is a gas distribution apparatus that is designed without the third frame and thus covering the second frame 211 directly on the first frame 210. It is noted that the gas distribution apparatus 20 shown in FIG. 6 is structurally the same as the one shown in FIG. 4, in that the second surface 2001 of the gas distribution apparatus 20 is connected to the process chamber 3 while allowing the at least one gas supply channel 2003 formed on the sidewall of the recess 2002 on the gas distribution apparatus 20 to communicate with the second gas source 23 so as to receive the flow of a second gas therefrom.

Please refer to FIG. 7C, which is a schematic diagram showing a first frame according to another embodiment of the invention. As shown in FIG. 7C, the first frame 210a is composed of a plate 2100a and the plural tubes 2101a, in that the plate 2100a is formed with a first recess 2102a having a plurality of via holes 2103a formed therein while allowing the plural protruding tubes 2101a to be fitted to their corresponding via holes 2103a. Different from that the first frame 210 and the plural protruding tubes 2101 are integrally formed or being assembled by welding, the first frame 210a and the plural protruding tubes 2101a shown in FIG. 7C can be assembled by screwing, or by tightly engagement, but is not limited thereby. Thereby, each of the plurality protruding tubes can be replaced independently when damaged without having to replace the whole first frame 210a so that not only the lifespan of the first frame 210a is prolonged, but also the maintenance cost is reduced.

Operationally, as soon as the first gas and the second gas, provided separately from the first gas source 22 and the second gas source 23, are fed into the gas distribution apparatus 2, the second gas will flow into the recess 2002 through the gas supply channel 2003, and then from the recess 2002 into the second channel 203 as the recess is designed communicating with the second channel 203; and simultaneously, the first gas will flow into the second recess 2120 of the third frame 212 through the gas supply channel 2110 of the second frame 211. Moreover, as there are via holes 2121 being formed on the bottom of the second recess 2120 that are designed communicating with the first recess 2100, the first gas after being uniformly distributed in the second recess 2120 can be guided to flow into the first recess 2100 uniformly where the first gas is able to flow into the first channel 201 through the protruding tubes 2101.

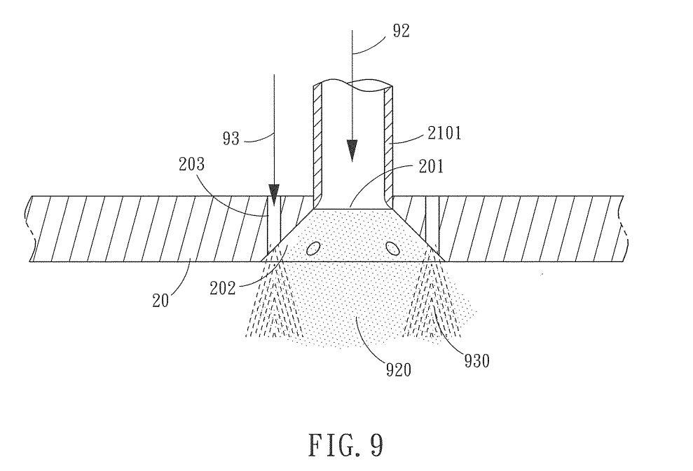

Please refer to FIG. 9, which is a schematic diagram showing how a first gas and a second gas are flowing in a gas distribution plate of the invention. When the first gas 92 flows into the tapered opening 202 of the first channel 201 through the protruding tubes 211, the covering range of the air curtain 920 resulting from the spraying of the first gas 92 will becoming larger and larger in proportion to the distance of the first gas 92 being spraying away from the tapered opening 202. It is because that the tapering of the tapered opening 202 will cause the flowing speed of the first gas 92 to slow down which is going to cause the spreading of the first gas 92. At the same time, the air curtain 930 resulting from the spraying of the second gas 93 into the tapered opening 202 through the second channel 203 will come into contact with the spreading air curtain 920 of the first gas 92 and thereafter mixed with the first gas 92 at the region close to the frame 20, so that the first gas 92 and the second gas 93 can be mixed in the early stage of their spreading and thus enabling the two the be mixed completely inside the process chamber 3 for enhancing the process efficiency of the process chamber 3. However, if there is no such design as the tapered opening 202, because of the flowing speeds of the first gas 92 and the second gas 93, the two gases will not spread and mix with each other until they are being sprayed away from the frame 20 for a conceivable distance which will cause the process efficiency of the process chamber 3 to drop. Hence, by the tapered opening 202, the first gas and the second gas can be mixed with each other properly after being sprayed away from the frame 20 so that process efficiency of the process chamber 3 is enhanced.

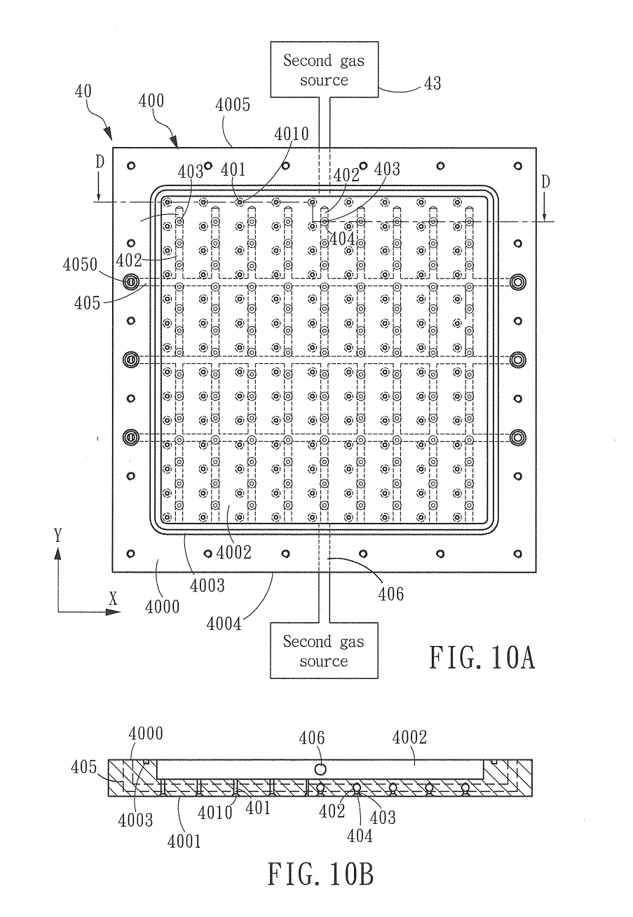

Please refer to FIG. 10A and FIG. 10B, which are respectively a top view and a D-D sectional view of a gas distribution plate according to a second embodiment of the invention. In this embodiment, the gas distribution plate 40 has a frame 400, a plurality of first channels 401, a plurality of second channels, and a plurality of third channels 403. The frame 400 is configured with a first surface 4000 and a second surface 4001 in a manner that there is a recess 4002 formed on the central area of the first surface 4000 by a means selected from the group consisting of: a means for performing a mechanical process upon the center of the frame 400, and a means for welding pieces of the frame 400 together while allowing the recess 4002 to be formed at the center thereof. In addition, there is a groove 4003 disposed surrounding the periphery of the recess 4002 to be used for receiving air-tightness components. Moreover, the plural first channels 401 are formed inside the recess 4002 while enabling them to penetrate the recess 4002 and the second surface 4001. Each of the plural first channels 401 has a first tapered opening 4010 formed at an end thereof close to the second surface 4001. The plural second channels 402 are formed inside the frame 40 while enabling each of the plural second channels 402 to be arranged perpendicular to the first gas supply channel 405. For the arrangement of the plural third channels 403, there are more than one third channels 403 being formed on each of the plural second channels 402 on the second surface 4001 while allowing the same to communicate with their corresponding second channels 402. Moreover, each third channel 403 is configured with a second tapered opening 404 as the tapered opening 404 is being located on the second surface 4001. In addition, there is at least one first gas supply channel 405 formed in an area between the wall of the recess 4002 and the side of the frame 40 in a direction defined by the Y-axis of FIG. 10A, while allowing each of the at least one first gas supply channel 405 to extend from its corresponding opening 4050 located on the first surface 4000 into the frame 40 and thus communicate with the second channel 402. Moreover, there is at least one second gas supply channel 406 formed in an area between the wall of the recess 4002 and the side of the frame 40 in a direction defined by the X-axis of FIG. 10A, while allowing each the at least one second gas supply channel 406 to be arranged boring through the frame from its third side 4004 to the fourth side 4005 and thus communicate with the recess 4002 through the opening formed on the sidewall of the recess 4002. It is noted that the amounts of the first gas supply channel 405 and the second gas supply channels 406 are determined according to actual requirement and can be selected at will that they are not limited by those demonstrated in the embodiments of the invention, not to mention the locations of the openings relating to those gas supply channels.

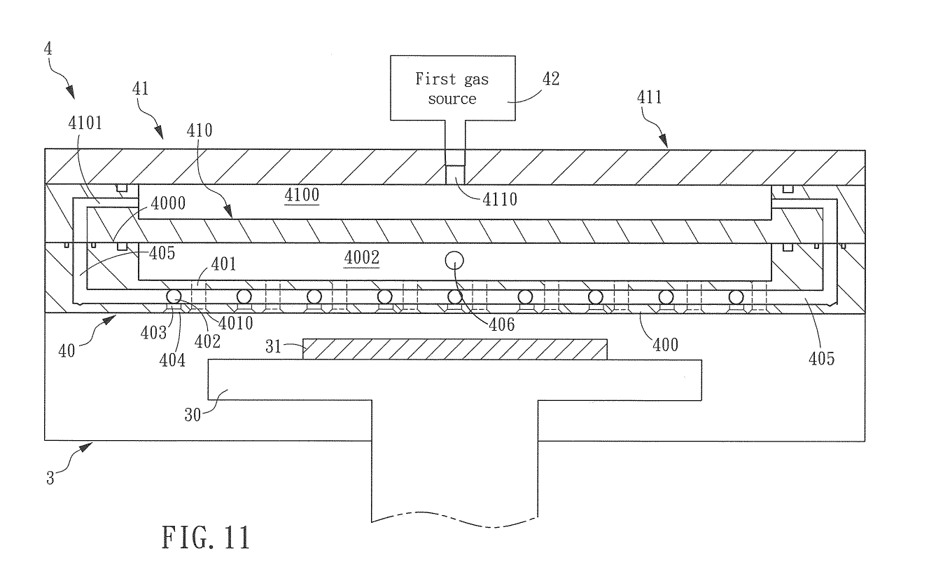

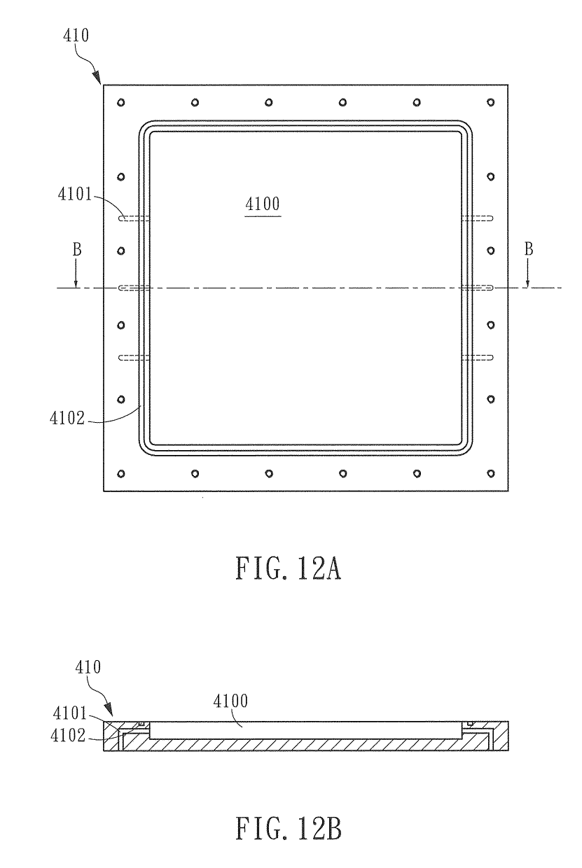

Please refer to FIG. 11, which is a schematic diagram showing a gas distribution apparatus according to a second embodiment of the invention. The gas distribution apparatus employs the gas distribution plate of FIG. 10A as its gas distribution mechanism for enabling two separate gases to be delivered independently into a process chamber. In this embodiment, the gas distribution apparatus 4 is disposed on a process chamber 3, which is characteristically the same as the aforesaid embodiment and thus will not describe further herein. The gas distribution apparatus 4 of FIG. 11 comprises: a gas guidance section 41; and a gas distribution plate 40, being arranged connecting to the gas guidance section 41; in which the gas guidance section 41 is coupled to a first gas source 42 for guiding the flow of a first gas from the first gas source 42 to the gas distribution plate 40; and the gas distribution plate 40 is further composed of: a first frame 410, and a second frame 411. Please refer to FIG. 12A and FIG. 12B, which are respectively a top view and a sectional view of a first frame used in the embodiment of FIG. 11. The first frame 410 is disposed covering the first surface 4000 of the gas distribution plate 40 whereas the first frame 410 is configured with a first recess 4100 at the center thereof and the recess 4100 can be formed by a means selected from the group consisting of: a means for performing a mechanical process upon the center of the first frame 410, and a means for welding pieces of the frame 410 together while allowing the recess 4100 to be formed at the center thereof. In addition, there is at least one guidance channel 4101 formed on the two sidewalls of the recess 4100 while enabling each to communicate with the first gas supply channel 405. In this embodiment, there are three guidance channels 4104 formed on each sidewall of the recess 4100, but it is not limited thereby. Moreover, for enhancing air tightness, there is a groove 4102 to be formed surrounding the periphery of the first recess 4100 to be used for receiving air-tightness components. Each first gas supply channel 405 is disposed boring inside the first frame 410 from an opening thereof located at a sidewall of the recess 4100 toward another opening located at the bottom of the first frame 410 while allowing the same to communicate with its corresponding first channel. In addition, the second frame 411, being disposed covering on the top surface of the first frame 410, is configured with a via hole 4110 capable of communicating with the first recess 4100 to be used for the first gas to flow therethrough.

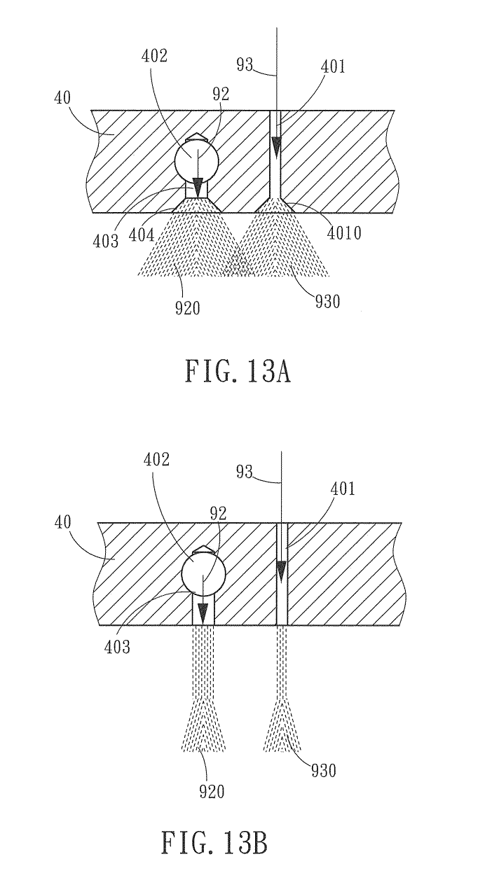

As shown in FIG. 10A and FIG. 11, the via hole 4110 is connect to the first gas source 42 so as to guide the first gas of the first gas source 42 to flow into the first recess 4100 where it is further guided to enter the first gas supply channel 405 through the guidance channels 4101 and thus into the process channel through the second channels 402 and the third channels 403. By the arrangement of the aforesaid first frame 410, the gas first is distributed inside the first recess 4100 of the first frame 410, and then is further being enabled to distribute uniformly as it is being guided into the second channels 402 of the frame 400 through the guidance channels 4101 before it is fed into the process chamber 3 through the third channels 403. The second gas source 43 is connected to the second gas supply channel 406 formed on a side of the frame 40 to be used for providing the second gas, by that the second gas is guide to flow into the recess 4002 of the frame 40 through the second gas supply channel 406 and then is fed into the process chamber through the first channel 401. With the aforesaid arrangement, the gas distribution apparatus 4 can allow two separate gases to be delivered independently into a process chamber 3 while enabling the gases to be mixed completely after entering the processing chamber 3. Please refer to FIG. 13A and FIG. 13B, which are schematic diagrams showing how a first gas and a second gas are mixed with and without the formation of tapered openings in respective. As shown in FIG. 13A, there are tapered openings 404, 4010 formed in the frame 40 of the gas distribution apparatus 4, by that the speeds of the gases flowing inside the gas channels are to slow down and thus cause those gases to spread, that is, it is going to cause the first gas 92 and the second gas 93 to mix with each other rapidly and uniformly. However, for the gas distribution apparatus 4 shown in FIG. 13B, the first gas 92 and the second gas 93 will leave the gas distribution plate at a comparatively higher speed in respective that the two gases 92, 93 will not spread and mix until they are at certain distances away from the frame 40 since there is not tapered openings.

With respect to the above description then, it is to be realized that the optimum dimensional relationships for the parts of the invention, to include variations in size, materials, shape, form, function and manner of operation, assembly and use, are deemed readily apparent and obvious to one skilled in the art, and all equivalent relationships to those illustrated in the drawings and described in the specification are intended to be encompassed by the present invention.

What is claimed is:

1. A gas distribution plate, comprising:
a frame, having a recess formed at the center thereof;
a first channel, connected to the recess by an end thereof while enabling another end thereof to penetrate the frame;
a tapered opening, capable of communicating with the first channel; and
at least one second channel, formed on the frame while enabling the same to communicate with the tapered opening.

2. The gas distribution plate of claim 1, wherein the at least one second channel is disposed surrounding the periphery of the first channel.

3. The gas distribution plate of claim 1, wherein the center axis of each second channel is arranged parallel with the center axis of the first channel.

4. The gas distribution plate of claim 1, wherein there is an included angle formed between the center axes of the first channel and the at least one second channel.

5. The gas distribution plate of claim 1, wherein the recess is formed by a means selected from the group consisting of: a means for performing a mechanical process upon the center of the frame, and a means for welding pieces of the frame together while allowing the recess to be formed at the center thereof.

6. The gas distribution plate of claim 5, wherein there is at least one gas supply channel being arranged at a side of the recess.

7. The gas distribution plate of claim 1, wherein the first channel and the frame are assembled in a manner selected from the group consisting of: the first channel is integrally formed with the frame, the first channel is connected to the frame by screwing, and the first channel is connected to the frame by tightly engagement.

8. A gas distribution apparatus, comprising:
a gas guidance section, for guiding the flow of a first gas;
a gas distribution plate, connected to the gas guidance section and comprising:
a frame, having a recess formed at the center thereof;
a plurality of first channels, each having an end connected to the recess and another end penetrating the frame while configuring each for enabling the same to communicate with the gas guidance section so as to received the first gas therefrom;
a plurality of second channels, being arranged in a manner that there is at least one such second channels disposed at a side of each first channel to be used for guiding the flow of a second gas; and
a plurality of tapered openings, each being formed for enabling the same to communicate with one corresponding first channel and the at least one second channels disposed at the side of the corresponding first channel.

9. The gas distribution apparatus of claim 8, wherein the recess is formed by a means selected from the group consisting of: a means for performing a mechanical process upon the center of the frame, and a means for welding pieces of the frame together while allowing the recess to be formed at the center thereof.

10. The gas distribution apparatus of claim 9, wherein there is at least one gas supply channel being arranged at a side of the recess, provided for the second gas to enter the recess.

11. The gas distribution apparatus of claim 8, wherein the at least one second channel is disposed surrounding the periphery of their corresponding first channel.

12. The gas distribution apparatus of claim 8, wherein the center axis of each second channel is arranged parallel with the center axis of the first channel.

13. The gas distribution apparatus of claim 8, wherein there is an included angle formed between the center axes of the first channel and the corresponding at least one second channel.

14. The gas distribution apparatus of claim 8, wherein the gas guidance section further comprising:
a first frame, disposed on the first surface, having a first recess formed on a side thereof and a plurality of protruding tubes at another side thereof while enabling each tube to communicate with the first recess as each is further capable of communicate with its corresponding first channel through an end thereof; and
a second frame, disposed covering on the first frame, having an air hole provided for the first gas to flow therethrough as it is being configured to communicate with the first recess.

15. The gas distribution apparatus of claim 14, further comprising:
a third frame, sandwiched between the first frame and the second frame, being configured with a second recess in a manner that there are a plurality of via holes formed on the bottom of the second recess while enabling the plural via holes to communicate with the first recess.

16. The gas distribution apparatus of claim 8, wherein the second surface is coupled to a process chamber.

17. The gas distribution apparatus of claim 14, wherein the first frame and the plural protruding tubes is assembled in a manner selected from the group consisting of: the first frame is connected to the plural protruding tubes by screwing, and the first frame is connected to the plural protruding tubes by tightly engagement.

18. The gas distribution apparatus of claim 16, wherein the second gas is enabled to flow into the second channels through the recess

19. A gas distribution plate, comprising:
a frame with a first surface and a second surface, having a recess formed at the center thereof;
a first channel, being formed penetrating through the recess of the frame;
a second channel, formed inside the frame while allowing the center axis of the second channel to align parallel with the first surface; and
a third channel, formed on the second surface of the frame while allowing the same to communicate with the second channel;
wherein, the first channel further has a first tapered opening located on the second surface, and the third channel further has a second tapered opening located on the second surface

20. The gas distribution plate of claim 19, wherein the recess is formed by a means selected from the group consisting of: a means for performing a mechanical process upon the center of the frame, and a means for welding pieces of the frame together while allowing the recess to be formed at the center thereof.

21. The gas distribution plate of claim 20, wherein there is at least one gas supply channel formed in an area between the wall of the recess and the side of the frame while allowing the at least one gas supply channel to communicate with the second channel.

22. A gas distribution apparatus, comprising:
a gas guidance section, for guiding the flow of a first gas;
a gas distribution plate, connected to the gas guidance section and comprising:
a frame with a first surface and a second surface, having a recess formed at the center thereof;
a plurality of first channels, each being formed penetrating through the recess of the frame to be used for guiding the flow of a second gas;
a plurality of second channels, each being formed inside the frame while allowing the center axis of each second channel to align parallel with the first surface so as to be used for guiding the flow of the first gas; and
a plurality of third channel, formed on the second surface of the frame while allowing the same to communicate with their corresponding second channels;
wherein, each first channel further has a first tapered opening located on the second surface, and each third channel further has a second tapered opening located on the second surface.

23. The gas distribution apparatus of claim 22, wherein the recess is formed by a means selected from the group consisting of: a means for performing a mechanical process upon the center of the frame, and a means for welding pieces of the frame together while allowing the recess to be formed at the center thereof.

24. The gas distribution apparatus of claim 23, wherein there is at least one first gas supply channel formed in an area between the wall of the recess and the side of the frame while allowing the at least one first gas supply channel to communicate with the second channel.

25. The gas distribution apparatus of claim 24, wherein the gas guidance section further comprising:
a first frame, disposed on the first surface, having a first recess formed on a side thereof in a manner that the first recess is capable of communicate with the at least one gas supply channel through its corresponding at least one guidance passageway formed on a sidewall of the first recess; and
a second frame, disposed covering on the first frame, having an air hole provided for the first gas to flow therethrough s it is being configured to communicate with the first recess.

26. The gas distribution apparatus of claim 25, wherein there is at least one second gas supply channel being arranged at a side of the recess, provided for the second gas to enter the recess.

27. The gas distribution apparatus of claim 22, wherein the second surface is coupled to a process chamber.

28. The gas distribution apparatus of claim 27, wherein the second gas is enabled to flow into the recess of the frame through the at least one gas supply channel and then is directed to flow into the process chamber through the first channel.
